(19) United States
(12) Patent Application Publication
(10) Pub. No.: US 2008/0079102 A1
(43) Pub. Date: Apr. 3, 2008

(54) Image sensor structure and method of fabricating the same

(75) Inventors: Yu-Hsien Chen, Hsinchu (TW); Min-San Huang, Hsinchu (TW); Chia-Chiang Wang, Taichung (TW)

Correspondence Address: BIRCH STEWART KOLASCH & BIRCH, PO BOX 747, FALLS CHURCH, VA, 22040-0747, US

(73) Assignee: Powerchip Semiconductor Corp.

(21) Appl. No.: 11/706,196

(22) Filed: Feb. 15, 2007

(30) Foreign Application Priority Data
Sep. 28, 2006 (TW) 95135947

(51) Int. Cl. H01L 31/00; H01L 21/00

(52) U.S. Cl. 257/431; 438/96; 257/E21.001; 257/E31.001

(57) ABSTRACT

A method for fabricating an image sensor structure is provided. The method of fabricating an image sensor structure includes providing a substrate. An image sensor interconnect structure is formed on the substrate. A patterned stop layer is formed on the image sensor interconnect structure. An electrode layer, a first doped amorphous silicon layer and a first undoped amorphous silicon layer are conformably formed on the patterned stop layer and the image sensor interconnect structure not covered by the patterned stop layer in sequence. The first undoped amorphous silicon layer, the first doped amorphous silicon layer and the electrode layer are partially removed until the patterned stop layer is exposed by a planarization process, and each of a remaining electrode layer, a remaining first doped amorphous silicon layer and a remaining first undoped amorphous silicon layer are separated by the patterned stop layer.

### BACKGROUND OF THE INVENTION

1. Field of the Invention

The invention relates to an image sensor structure and method of fabricating the same, and more particularly to a photodiode layer of a photoconductor on active pixel (POAP) image sensor structure and method of fabricating the same.

2. Description of the Related Art

Photoconductor on active pixel (POAP) image sensors are widely applied in a variety of fields such as digital cameras, digital video cameras, monitors and mobile phones. POAP image sensors employ photoconductors, such as photodiode covered active pixels or image sensor cell arrays, to convert optical light into electrical signal.

POAP image sensors are capable of detecting light of various wavelengths such as visible light, X-ray, ultraviolet (UV) and infrared ray (IR). Electrons are generated by an incidental light absorbed by photoconductors formed on the top of the POAP image sensors, and transported to circuits below the photoconductors. Compared with conventional image sensors, POAP image sensors have higher photosensitivity, better light collection, and higher pixel density. FIG. 1 is a cross sectional view of a conventional POAP image sensor structure 10. An incidental light passes through a transparent conductive layer 145 in a pixel region (N-1, 1) or (N, 1) to a photodiode structure 135. The photodiode structure 135 converts the incident light into an electrical signal and transports the electrical signal to an active region 130 in a substrate 11.

For POAP image sensors to achieve advantages such as high image quality, low crosstalk, low noise and high quality image, a dark environment is desirable. In the conventional POAP image sensor structure 10, however, the photodiode structure 135 in different pixel regions (N-1, 1) and (N, 1) is a continuous layer as shown in FIG. 1. Incidental light with a large angle radiates in a pixel region (N-1, 1). The electrical signal converted by the photodiode structure 135 in the pixel region (N-1, 1) is transported to the active region 130 of the adjacent pixel region (N, 1) because the continuous photodiode structure 135. In other words, crosstalk may occur when current flows from higher-potential pixel region (N-1, 1) to neighboring, lower-potential, pixel region (N, 1), which results in blurred image, reduced resolution, and color transposition. Thus, the performance of the image sensor structure suffers. The crosstalk problem is more serious when the density of the image sensor is increased by shrinking the pixel area or using a multi-layer dielectric structure.

An image sensor structure with low crosstalk capable of solving the described problems is desirable.

### BRIEF SUMMARY OF INVENTION

A detailed description is given in the following embodiments with reference to the accompanying drawings.

An image sensor structure and method of fabricating the same are provided. An exemplary embodiment of a method for fabricating an image sensor structure comprises: providing a substrate; forming an image sensor interconnect structure on the substrate; forming a patterned stop layer on the image sensor interconnect structure; conformably forming an electrode layer, a first doped amorphous silicon layer and a first undoped amorphous silicon layer on the patterned stop layer and the image sensor interconnect structure not covered by the patterned stop layer in sequence; partially removing the first undoped amorphous silicon layer, the first doped amorphous silicon layer and the electrode layer until the patterned stop layer is exposed by a planarization process, and each of a remaining electrode layer, a remaining first doped amorphous silicon layer and a remaining first undoped amorphous silicon layer are separated by the! patterned-stop-layer.

An exemplary embodiment of an image sensor structure comprises: a substrate; an image sensor interconnect structure formed on the substrate; and a patterned stop layer formed on the image sensor interconnect structure to define a plurality of pixel regions, wherein each of the pixel region comprises an electrode layer and a first doped amorphous silicon layer formed on the image sensor interconnect structure not covered by the patterned stop layer and adjacent to the patterned stop layer.

### BRIEF DESCRIPTION OF DRAWINGS

The invention can be more fully understood by reading the subsequent detailed description and examples with references made to the accompanying drawings, wherein:

FIG. 1 shows a cross section of a conventional POAP image sensor structure.

FIGS. 2a to 2f show cross sections of an exemplary embodiment of an image sensor structure of the invention.

FIGS. 3a, 4a, 5a and 6a are space electrostatic potential simulation results of an exemplary embodiment of a photodiode layer using a software TCAD provided by Synopsy Co.

FIGS. 3b, 4b, 5b and 6b are space conduction current density simulation results of FIGS. 3a, 4a, 5a and 6a using a software TCAD provided by Synopsy Co.

FIGS. 7a and 8a are space electrostatic potential simulation results of another exemplary embodiment of a photodiode layer using a software TCAD provided by Synopsy Co.

FIGS. 7b and 8b are space conduction current density simulation results of FIGS. 7a and 8a using a software TCAD provided by Synopsy Co.

### DETAILED DESCRIPTION OF INVENTION

The following description is of the best-contemplated mode of carrying out the invention. This description is made for the purpose of illustrating the general principles of the invention and should not be taken in a limiting sense. The scope of the invention is best determined by reference to the appended claims.

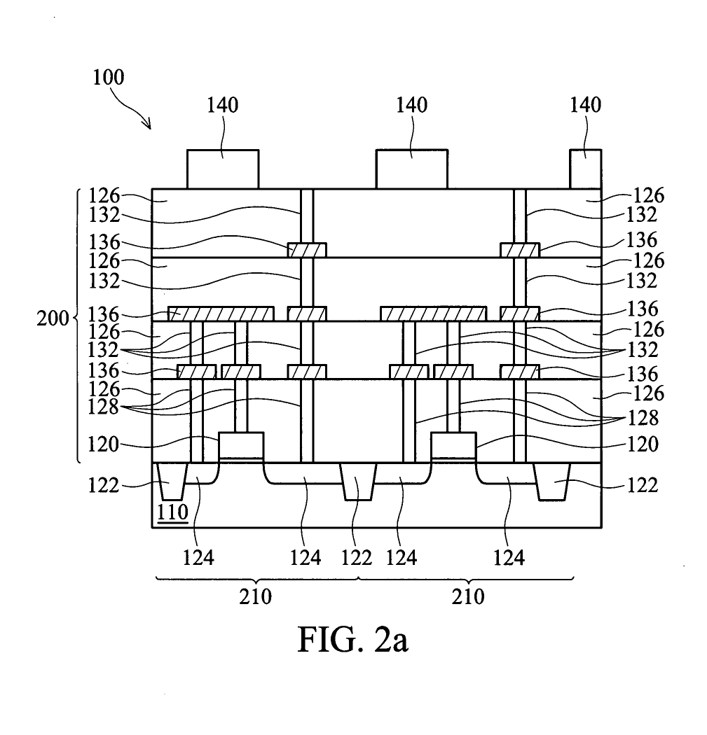

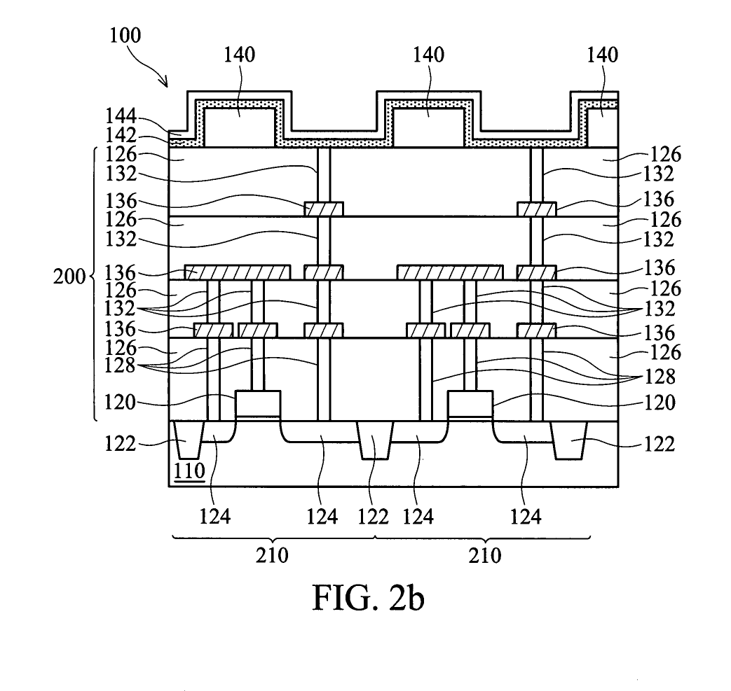

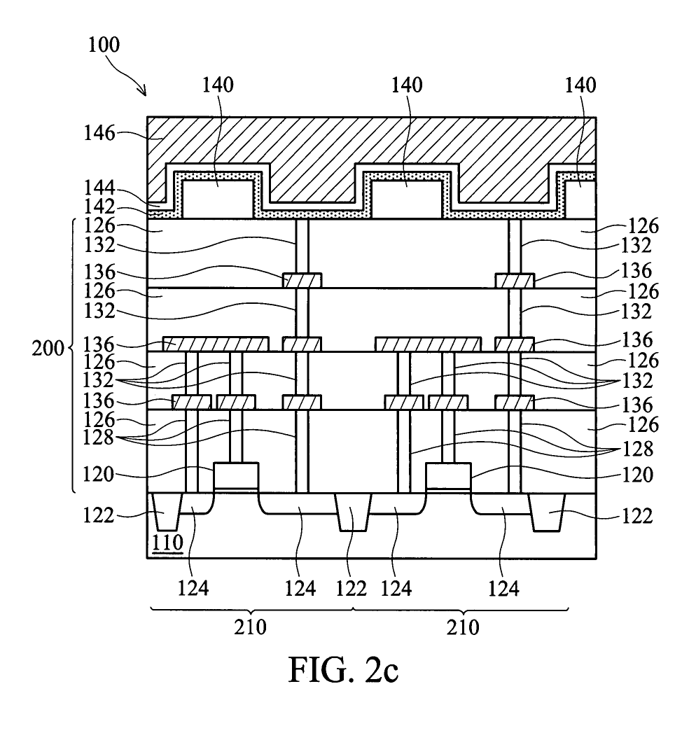

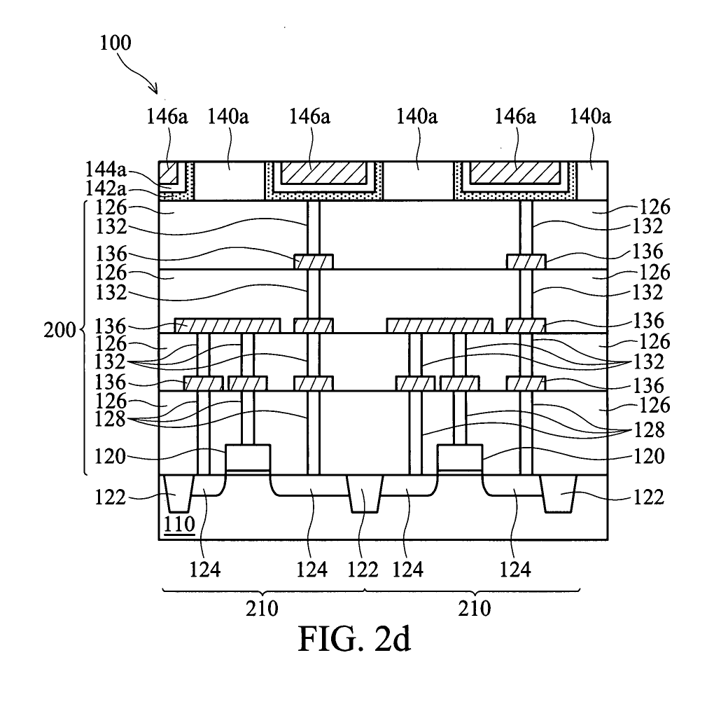

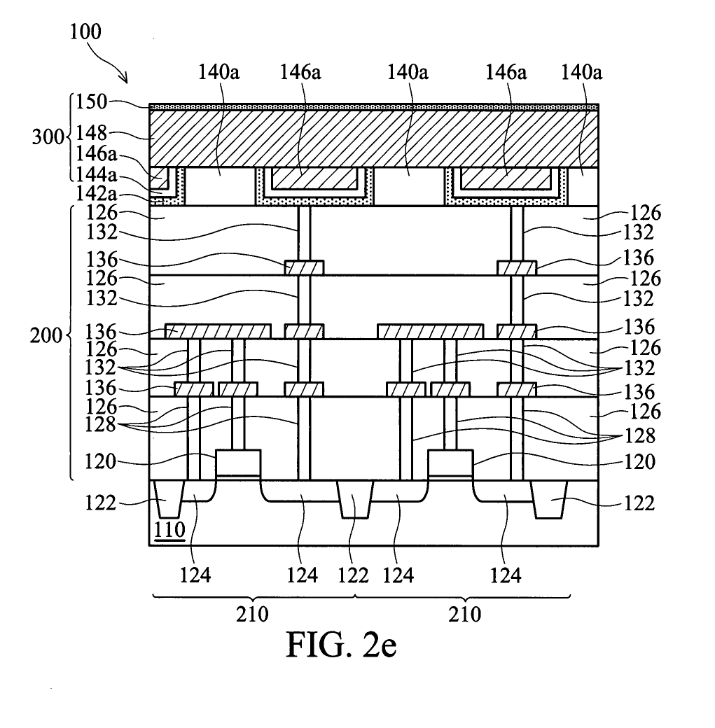

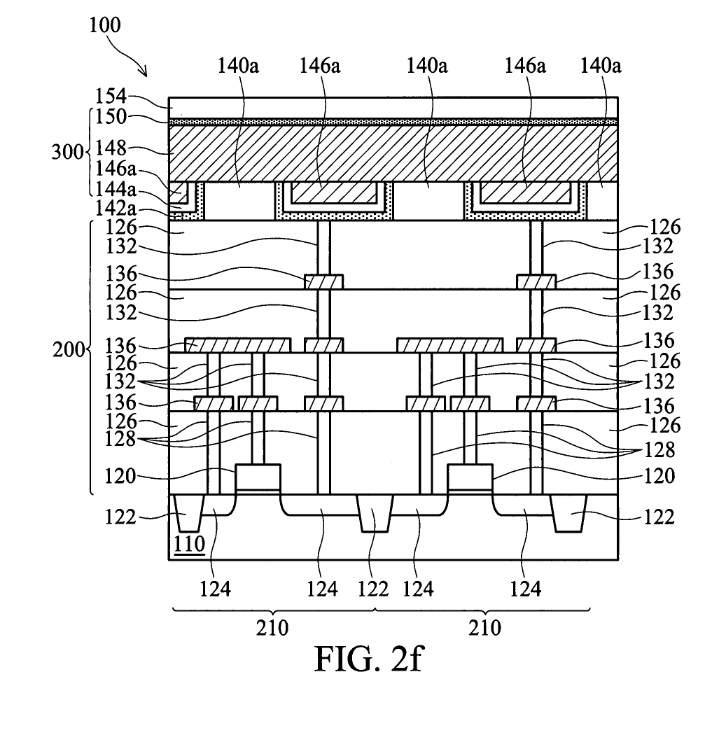

FIGS. 2a to 2f show cross sections of various embodiments of a process for fabricating an image sensor structure. Wherever possible, the same reference numbers are used in the drawings and the descriptions to the same or like parts.

FIG. 2a to 2f show cross sections of an exemplary embodiment of an image sensor structure 100. FIG. 2a shows the primary elements of the image sensor structure 100. Image sensor structure 100 comprises a substrate 110 comprising a plurality of pixel regions 210. The substrate 110 may comprise silicon, silicon on insulator (SOI) substrate, or other commonly used semiconductor substrate. A plurality of shallow trench isolations (STI) 122 is formed in the substrate 110. One or a plurality of image sensor interconnect structures 200 is respectively formed in each pixel region 210. The image sensor interconnect structure 200 may comprise CMOS transistors 120, interlayer dielectric (ILD) layers 126 formed thereon, contacts 128, metal interconnects 136 and vias 132. The contacts 128, the metal interconnects 136 and vias 132 electrically connect the CMOS transistors 120 and source/drain regions 124 in the pixel region 210. The ILD layer 126 may comprise SiO₂, SiNₓ, SiON, PSG, BPSG, F-containing SiO₂ and other low-k materials with a dielectric constant of less than 3.9. The metal interconnects 136 may comprise aluminum (Al), aluminum-alloy, copper (Cu), copper-alloy or other copper-based conductive materials. The contacts 128 and the vias 132 may comprise tungsten (W), aluminum (Al), copper (Cu) or silicides. A patterned stop layer 140, is formed on the image sensor interconnect to separate each pixel region 210 by lithography and etching processes. The patterned stop layer 140 is used as a stop layer for a following electrode layer 142 and a first doped amorphous silicon (α-Si) layer 144 removal process. The patterned stop layer 140 may comprise silicon nitride (Si₃N₄) and preferably has a thickness of about 100 Å to 1000 Å.

Referring to FIG. 2b, an electrode layer 142 is conformably formed on the patterned stop layer 140 and the image sensor interconnect structure 200. The vias 132 are formed in each pixel region 210 and electrically connected the electrode layer 142. The electrode layer 142 may comprise titanium nitride (TiN), aluminum, aluminum-alloy, copper, copper-alloy or other copper-based conductive material with a thickness of about 200 Å to 1000 Å. Next, a first doped amorphous silicon (α-Si) layer 144 is formed on the electrode layer 142 by a deposition process such as plasma enhanced chemical vapor deposition (PECVD), low pressure chemical vapor deposition (LPCVD), atmosphere CVD (ATCVD) or other deposition processes.

Referring to FIG. 2c, a first undoped amorphous silicon layer 146 is formed on the first doped amorphous silicon layer 144 and substantially forms a plane surface by a deposition process such as plasma enhanced chemical vapor deposition (PECVD), low pressure chemical vapor deposition (LPCVD), atmosphere CVD (ATCVD) or other deposition processes.

Referring to FIG. 2d, a planarization process such as chemical mechanical polishing (CMP) process is carried out to partially remove the first undoped amorphous silicon layer 146, the first doped amorphous silicon layer 144 and the electrode layer 142 until the patterned stop layer 140 is exposed. The patterned stop layer 140 serves as a polishing stop layer, thus, each of a remaining electrode layer 142a, a remaining first doped amorphous silicon layer 144a and a remaining first undoped amorphous silicon layer 146a is separated by a remaining patterned stop layer 140a. Proper CMP process conditions such as polishing time, and slurry material are desirable, thus, each of the remaining electrode layer 142a, the remaining first doped amorphous silicon layer 144a and the remaining first undoped amorphous silicon layer 146a is a discontinuous layer.

Next, referring to FIG. 2e, a second undoped amorphous silicon layer 148 and a second doped amorphous silicon layer 150 are formed on the remaining electrode layer 142a, the remaining first doped amorphous silicon layer 144a and the remaining first undoped amorphous silicon layer 146a to form a photodiode layer 300 in sequence. The photodiode layer 300 is a composite layer comprising the remaining first doped amorphous silicon layer 144a, the remaining first undoped amorphous silicon layer 146a, the second undoped amorphous silicon layer 148 and the second doped amorphous silicon layer 150. The remaining first undoped amorphous silicon layer 146a and the second undoped amorphous silicon layer 148 are neutral layers formed of the same material. The remaining first doped amorphous silicon layer 144a and the second doped amorphous silicon layer 150 are of different conductive types. For example, the first doped amorphous layer 144a is n-type while the second doped amorphous layer 150 is p-type, or the first doped amorphous layer 144a is p-type while the second doped amorphous layer 150 is n-type. The photodiode layer 300 preferably has a thickness of about 3000 Å to about 8000 Å.

Referring to FIG. 2f, a transparent conductive layer 154 is formed on the photodiode layer 300 by, for example, vacuum evaporation, sputtering, chemical vapor deposition or sol-gel dip-coating. The transparent conductive layer 154 may comprise indium-tin-oxide (ITO), tin oxide, titanium nitride, thin salicide, or the like. A voltage is applied to the transparent conductive layer 154 to reverse-bias the photodiode layer 300. Electrons are generated by an incidental light absorbed by the photodiode layer 300 and transported to the image sensor interconnect structure 200 in the pixel region 210 to output an electrical signal. Thus, fabrication of the image sensor structure 100 complete.

The aforementioned image sensor structure 100 comprises a substrate 110. An image sensor interconnect structure 200 is formed in each pixel region 210. A patterned stop layer 140a is formed on the image sensor interconnect structure 200 and defines a plurality of pixel regions 210. Each pixel region 210 comprises a remaining electrode layer 142a, a remaining first doped amorphous silicon layer 144a and a remaining first undoped amorphous silicon layer 146a formed on the image sensor interconnect structure 200 and surrounded by the patterned stop layer 140a. Each of the remaining electrode layer 142a, the remaining first doped amorphous silicon layer 144a and the remaining first undoped amorphous silicon layer 146a is a discontinuous layer. A second undoped amorphous silicon layer 148 and a second doped amorphous silicon layer 150 are formed on the remaining electrode layer 142a, the remaining first doped amorphous silicon layer 144a and the remaining first undoped amorphous silicon layer 146a to form a photodiode layer 300 in sequence. The photodiode layer 300 is a composite layer comprising the remaining first doped amorphous silicon layer 144a, the remaining first undoped amorphous silicon layer 146a, the second undoped amorphous silicon layer 148 and the second doped amorphous silicon layer 150. A transparent conductive layer 154 is formed on the photodiode layer 300.

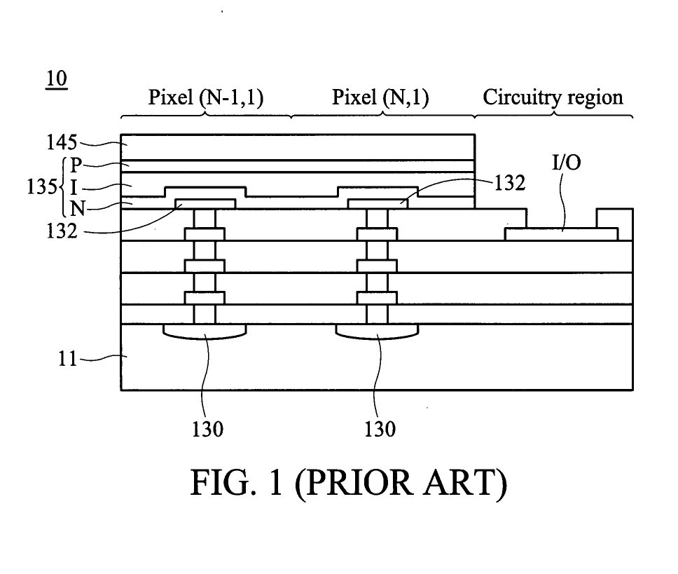

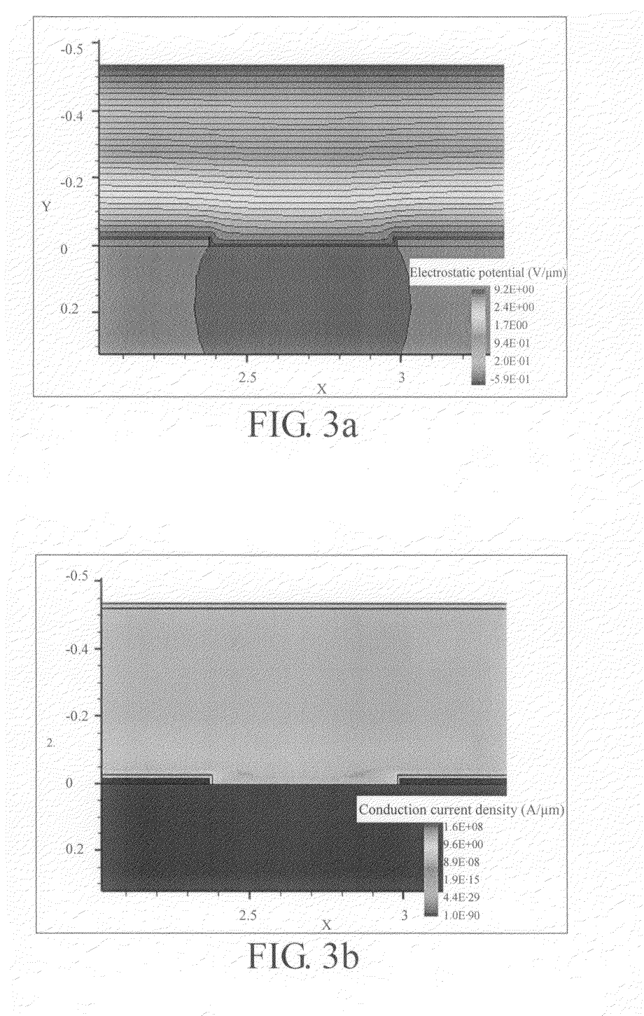

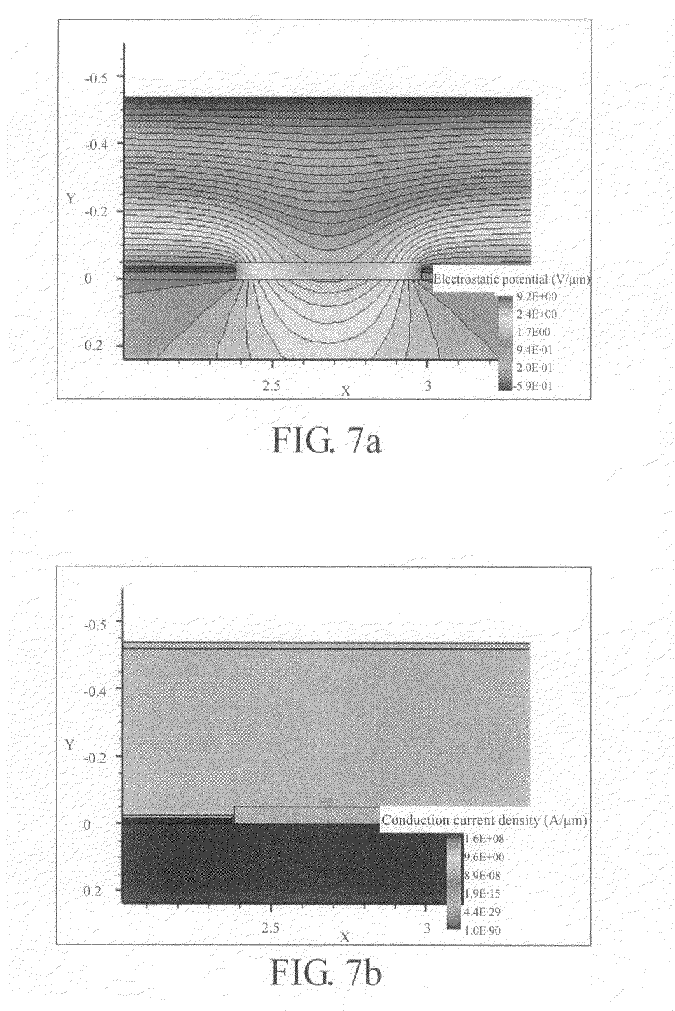

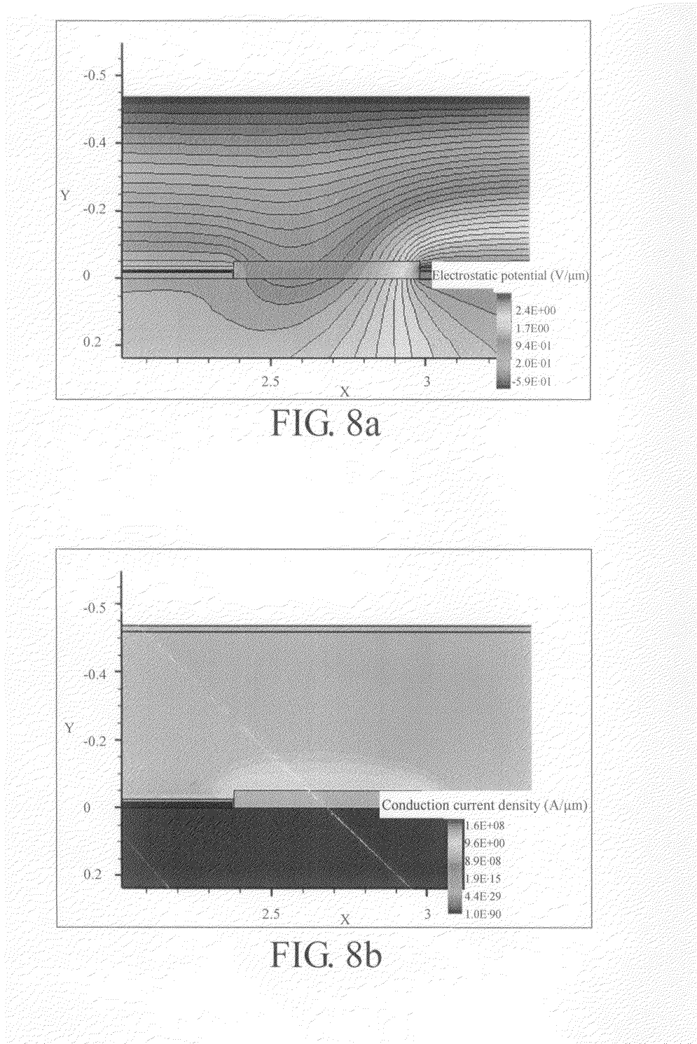

FIGS. 3a, 4a, 5a and 6a are space electrostatic potential simulation results of a conventional photodiode layer (the first doped amorphous silicon layer N of the photodiode structure 135 is a continuous layer as shown in FIG. 1) and an exemplary photodiode layer 300 of the image sensor structure 100 (the remaining first doped amorphous silicon layer 144a is a discontinuous layer). Both the first doped amorphous silicon layer N and the remaining first doped amorphous silicon layer 144a have a lower dopant concentration (1 E⁻¹²). FIGS. 3b, 4b, 5b and 6b are space conduction current density simulation results of FIGS. 3a, 4a, 5a and 6a. FIGS. 7a and 8a are space electrostatic potential simulation results of the photodiode layer 300 of the image sensor structure 100, which has a higher dopant concentration (1 E⁻⁶). FIGS. 7b and 8b are space conduction current density simulation results of FIGS. 7a and 8a. Software TCAD provided by Synopsy Co. is used to obtain, the simulation results shown in FIGS. 3 to 8. The aforementioned space electrostatic potential and current density simulation results show crosstalk evaluation in the adjacent pixel regions. Generally speaking, crosstalk evaluation has no standard. Because the resolution of the detected current is of about 1 E⁻¹², the crosstalk can not be ignored while the detected current is higher than of about 1 E⁻⁹.

FIGS. 3a and 3b are space electrostatic potential and space conduction current density simulation results of the conventional photodiode layer 135. The first doped amorphous silicon layer N of the conventional image sensor structure 10 has a lower dopant concentration (1 E⁻¹²). The applied voltages of the electrode layers 132 in the adjacent pixel regions of the conventional image sensor structure 10 are both 2.6V. The applied voltage of the transparent electrode layer 145 is 0V. No space electrostatic potential is produced while the applied voltages of electrode layers 132 are the same between the adjacent pixel regions, and the space conduction current density is of about 2.206 E⁻¹⁶ as shown in FIGS. 3a and 3b. There is no current between the two adjacent pixel regions, thus no crosstalk is occurred.

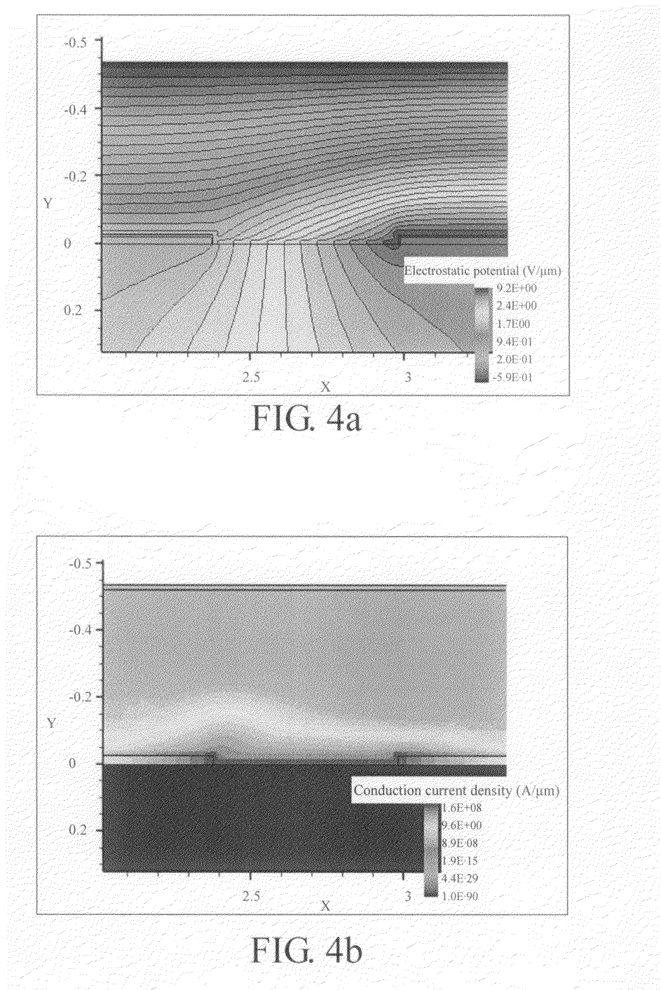

FIGS. 4a and 4b are space electrostatic potential and space conduction current density simulation results of the conventional photodiode layer 135. The first doped amorphous silicon layer N of the conventional image sensor structure 10 has a lower dopant concentration (1 E⁻¹²). The applied voltages of the electrode layers 132 in the adjacent pixel regions of the conventional image sensor structure 10 are 1.2V and 2.6V, separately. The applied voltage of the transparent electrode layer 145 is 0V. The space electrostatic potentials is thus produced while the applied voltages of electrode layers 132 have a difference between the adjacent pixel regions, and the space conduction current density is of about 1.205 E⁻² as shown in FIGS. 4a and 4b. An obvious crosstalk is occurred.

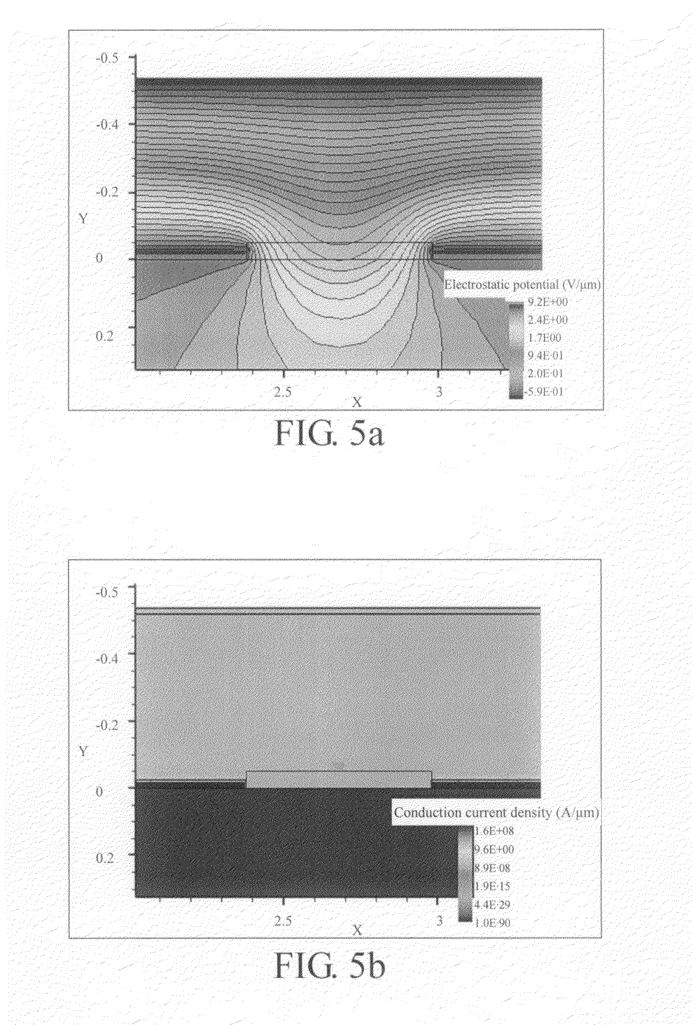

FIGS. 5a and 5b are space electrostatic potential and space conduction current density simulation results of an exemplary photodiode layer 300 of the image sensor structure 100. The remaining first doped amorphous silicon layer 144a of the image sensor structure 100 has a lower dopant concentration (1 E⁻¹²). The photodiode layer 300 of the image sensor structure 100 is a discontinuous layer separated by the patterned stop layer 140a. The applied voltages of the electrode layers 142a in the adjacent pixel regions 210 of the image sensor structure 100 are both 2.6 V. The applied voltage of the transparent electrode layer 154 is 0V. There is a potential barrier provided by the patterned stop layer 140a between the adjacent pixel regions 210. No space electrostatic potential is produced while the applied voltages of electrode layers 142a are the same, and the space conduction current density is of about 2.551 E⁻¹⁷ as shown in FIGS. 5a and 5b. There is no current between the two adjacent pixel regions, thus no crosstalk occurs.

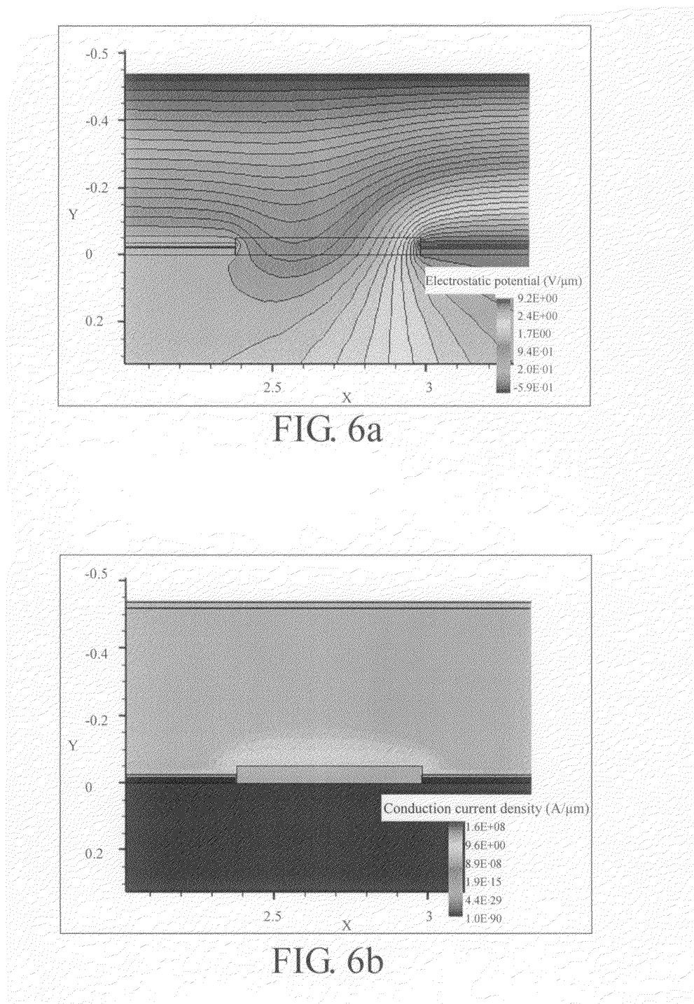

FIGS. 6a and 6b are space electrostatic potential and space conduction current density simulation results of an exemplary photodiode layer 300 of the image sensor structure 100. The remaining first doped amorphous silicon layer 144a of the image sensor structure 100 has a lower dopant concentration (1 E⁻¹²). The photodiode layer 300 of the image sensor structure 100 is a discontinuous layer separated by the patterned stop layer 140a. The applied voltages of the electrode layers 142a in the adjacent pixel regions of the image sensor structure 100 are, separately, 1.2V and 2.6V. The applied voltage of the transparent electrode layer 154 is 0V. Because the patterned stop layer 140a is an insulating layer, no space electrostatic potential is produced while the applied voltages of electrode layers 142a have a difference between the adjacent pixel regions 210, and the space conduction current density is about 1.43 E⁻¹³ as shown in FIGS. 6a and 6b. No crosstalk occurs. This embodiment of image sensor structure 100 can suppress crosstalk even if the applied voltages are different between the adjacent pixel regions 210.

Because an embodiment of image sensor structure 100 can suppress crosstalk between the adjacent pixel regions 210, the dopant concentration of the remaining first doped amorphous silicon layer 144a can be increased to improve the performance of the image sensor structure 100. FIGS. 7a and 7b are space electrostatic potential and space conduction current density simulation results of the photodiode layer 300 of the image sensor structure 100 in another embodiment. The remaining first doped amorphous silicon layer 144a of the image sensor structure 100 has a higher dopant concentration (1 E⁻⁶). The applied voltages of the electrode layers 142a in the adjacent pixel regions 210 of the image sensor structure 100 are both 2.6V. The applied voltage of the transparent electrode layer 154 is 0V. There is a potential barrier between the adjacent pixel regions 210. No space electrostatic potential is produced while the applied voltages of electrode layers 142a are the same, and the space conduction current density is of about 2.712 E⁻¹⁴ as shown in FIGS. 7a and 7b. There is no current between the two adjacent pixel regions, thus, no crosstalk occurs.

FIGS. 8a and 8b are space electrostatic potential and space conduction current density simulation results of the photodiode layer 300 of the image sensor structure 100 in another embodiment. The remaining first doped amorphous silicon layer 144a of the image sensor structure 100 has a higher dopant concentration (1 E⁻⁶). The applied voltages of the electrode layers 142a in the adjacent pixel regions of the image sensor structure 100 are, separately, 1.2V and 2.6V. The applied voltage of the transparent electrode layer 154 is 0V. Because the patterned stop layer 140a is an insulating layer, as shown in FIG. 8a, there is a potential barrier between the adjacent pixel regions 210 and even the applied voltages of electrode layers 142a have a difference between the adjacent pixel regions 210 and the dopant concentration of the remaining first doped amorphous silicon layer 144a is high. No current is generated (the space conduction current density is of about 1.526 E⁻¹³) between the adjacent pixel regions 210 as shown in FIG. 8b, thus no crosstalk occurs. The image sensor structure 100 possesses advantages of low crosstalk and high performance.

In the described, the first doped amorphous layer 144a of the image sensor structure 100 is a discontinuous layer. Thus, the detected image signal in one pixel region does not affect the adjacent pixel region. The crosstalk problem can thus be reduced. The carrier mobility can be improved by increasing the dopant concentration of the remaining first doped amorphous silicon layer 144a. When a voltage is applied to the transparent conductive layer 154 to reverse-bias the photodiode layer 300, a larger depletion region is extended into the remaining first undoped amorphous silicon layer 146a and the second undoped amorphous silicon layer 148. Consequently, more electron-hole pairs are generated by the larger depletion region. Furthermore, lower contact resistance between the first doped amorphous layer 144a and the patterned electrode layer 142a can be achieved by increasing the dopant concentration of the first doped amorphous layer 144a. Ohmic contact between the first doped amorphous layer 144a and the electrode layer 142a is then formed, and the performance of the image sensor structure 100 is improved. The first doped amorphous layer 144a is cut off by controlling CMP process conditions such as polishing time, slurry material without requiring any additional lithography and etching processes. The advantages of lower manufacturing costs and higher manufacturing yield can thus be achieved.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method of fabricating an image sensor structure, comprising:
providing a substrate;
forming an image sensor interconnect structure on the substrate;
forming a patterned stop layer on the image sensor interconnect structure;
conformably forming an electrode layer, a first doped amorphous silicon layer and a first undoped amorphous silicon layer on the patterned stop layer and the image sensor interconnect structure in sequence; and
partially removing the first undoped amorphous silicon layer, the first doped amorphous silicon layer and the electrode layer until the patterned stop layer is exposed by a planarization process, and each of a remaining electrode layer, a remaining first doped amorphous silicon layer and a remaining first undoped amorphous silicon layer being separated by the patterned stop layer.

2. The method of fabricating the image sensor structure as claimed in claim 1, wherein the planarization process comprises a chemical mechanical polishing process.

3. The method of fabricating the image sensor structure as claimed in claim 1, further comprising:
forming a second undoped amorphous silicon layer, a second doped amorphous silicon layer on the remaining electrode layer, the remaining first doped amorphous silicon layer and the remaining first undoped amorphous silicon layer to form a photodiode layer, wherein the photodiode layer is a composite layer comprising the remaining first doped amorphous silicon layer, the remaining first undoped amorphous silicon layer, the second undoped amorphous silicon layer and the second doped amorphous silicon layer.

4. The method of fabricating the image sensor structure as claimed in claim 3, wherein the first undoped amorphous silicon layer and the second undoped amorphous silicon layer comprise the same material.

5. The method of fabricating the image sensor structure as claimed in claim 3, further comprising:
forming a transparent conductive layer on the photodiode layer.

6. The method of fabricating the image sensor structure as claimed in claim 3, wherein the first doped amorphous silicon layer is n-type while the second doped amorphous silicon layer is p-type, or the first undoped amorphous silicon layer is p-type while the second doped amorphous silicon layer is n-type.

7. The method of fabricating the image sensor structure as claimed in claim 3, wherein the photodiode layer is formed by chemical vapor deposition process.

8. The method of fabricating the image sensor structure as claimed in claim 1, wherein forming the patterned stop layer comprises:
forming a nitride layer on the image sensor interconnect structure; and
patterning the nitride layer by lithography and etching processes.

9. An image sensor structure, comprising:
a substrate;
an image sensor interconnect structure formed on the substrate; and
a patterned stop layer formed on the image sensor interconnect structure to separate a plurality of pixel regions, wherein each of the pixel region comprises an electrode layer and a first doped amorphous silicon layer formed on the image sensor interconnect structure and surrounded by the patterned stop layer.

10. The image sensor structure as claimed in claim 9, wherein each of the electrode layer and the first doped amorphous silicon layer is a discontinuous layer separated by the patterned stop layer.

11. The image sensor structure as claimed in claim 9, wherein each of the pixel regions comprises a first undoped amorphous silicon layer formed on the first doped amorphous silicon layer.

12. The image sensor structure as claimed in claim 9, wherein the patterned stop layer comprises nitride.

13. The image sensor structure as claimed in claim 9, wherein the patterned electrode layer comprises titanium nitride, aluminum, aluminum-alloy, copper, copper-alloy or copper-based conductive materials.

14. The image sensor structure as claimed in claim 11, further comprising:
a second undoped amorphous silicon layer and a second doped amorphous silicon layer formed on the patterned stop layer and the pixel regions in sequence to form a photodiode layer, wherein the photodiode layer is a composite layer comprising the first doped amorphous silicon layer, the first undoped amorphous silicon layer, the second undoped amorphous silicon layer and the second doped amorphous silicon layer.

15. The image sensor structure as claimed in claim 14, wherein the first doped amorphous layer is n-type while the second doped amorphous layer is p-type, or the first undoped amorphous layer is p-type while the second doped amorphous layer is n-type.

16. The image sensor structure as claimed in claim 14, further comprising:
a transparent conductive layer formed on the photodiode layer.

17. The image sensor structure as claimed in claim 16, wherein the transparent conductive layer comprises indium-tin-oxide, tin dioxide, titanium nitride or thin salicide.
